(19) United States
(12) Patent Application Publication
(10) Pub. No.: US 2025/0258216 A1
(43) Pub. Date: Aug. 14, 2025

(54) FAULT DIAGNOSIS METHOD FOR THE RF FRONT-END CIRCUIT OF A MIMO SYSTEM

(71) Applicant: UNIVERSITY OF ELECTRONIC SCIENCE AND TECHNOLOGY OF CHINA, Chengdu (CN)

(72) Inventors: Zhen LIU, Chengdu (CN); Xiaoting TANG, Chengdu (CN); Yuhua CHENG, Chengdu (CN); Yidong LIN, Chengdu (CN); Hang GENG, Chengdu (CN); Yuhang LIANG, Chengdu (CN); Gen QIU, Chengdu (CN); Min WANG, Chengdu (CN); Jinhua MI, Chengdu (CN); Xiuyun ZHOU, Chengdu (CN); Bing LONG, Chengdu (CN)

(73) Assignee: UNIVERSITY OF ELECTRONIC SCIENCE AND TECHNOLOGY OF CHINA, Chengdu (CN)

(21) Appl. No.: 19/196,865

(22) Filed: May 2, 2025

(30) Foreign Application Priority Data
Jan. 7, 2025 (CN) 202510021468.7

(51) Int. Cl. G01R 31/28

(52) U.S. Cl. CPC G01R 31/2822; G01R 31/2839

(57) ABSTRACT

A fault diagnosis method for the RF front-end circuit of a MIMO system includes using a Synchronous Enhancement Extracting Transform (SEET) to pre-process the acquired fault signal to extract fault feature, creating a fault identification model fused by a complex field based asymmetric convolutional neural network and a complex field based multi-head attention module to assign fault feature weights, extract key feature and identify fault status. The SEET can extract fault feature components, and calculate its real field feature and imaginary field feature to obtain a real field two-dimensional matrix i and an imaginary field two-dimensional matrix q, thus an enhanced time-frequency feature is obtained. The fault identification model is used for a transform from a complex field feature space to a high dimensional space and realizing the assignment of fault feature weights, key features extraction and fault status identification.

### FIELD OF THE INVENTION

This application claims priority under the Paris Convention to Chinese Patent Applications No. 202510021468.7, filed on Jan. 1, 2025, the entirety of which is hereby incorporated by reference for all purposes as if fully set forth herein.

The present invention relates to the field of fault diagnosis, more particularly to a fault diagnosis method for RF (Radio Frequency) front-end circuit of MIMO (Multi-Input Multi-Output) system.

### BACKGROUND OF THE INVENTION

RF front-end circuit is the core part of massive multi-input multi-output systems such as radar and communication system, and undertakes key signal processing functions such as the transmission, reception, amplification and filtering of RF signal, its state has great impact on the performance and stability of the whole MIMO system. Affected by high-frequency loss and environment interference, a fault or faults often occur in RF front-end circuit. For example, high frequency loss causes the impedance mismatch of RF front-end circuit and transmission attenuation of RF signal, environment interference causes the aging of components of RF front-end circuit, which makes the overall function and reliability of RF front-end circuit decreased.

Implementing an appropriate fault diagnosis on RF front-end circuit can guarantee continuous functionality and performance of MIMO system, and improve the performance and stability of the whole MIMO system. As the complexity and integration of function and structure of RF front-end circuit increase continuously, the volume of circuit parameters also increases continuously. Meanwhile, affected by complex environment interferences, the complexity of variation of circuit parameters increases further. In addition, mutual coupling effect from faults and interferences also makes the applicability of traditional fault diagnosis dramatically deceased in circuit modeling, fault feature extraction and fault identification.

However, through the effective combination of the time-frequency analysis based fault feature extraction and the deep learning based fault identification model, the above-mentioned limitations in fault diagnosis on RF front-end circuit can be overcome to realize a quick and accurate fault diagnosis.

In the time-frequency analysis based fault feature extraction, the time domain feature and the frequency domain feature of the signal outputted by RF front-end circuit are combined to obtain the fault information that is confused by the noise and interference caused by circuit error and nonlinearity, which enhances the accuracy of fault diagnosis. Research shows that traditional time-frequency analyses, such as Short-time Fourier Transform (STFT), Wigner-Vile Distribution (WVD) and Empirical Mode Decomposition (EMD) can't simultaneously obtain high-accuracy time resolution and high-accuracy frequency resolution, which adversely affects the feature extraction of rapid time-varying waveform. Compared with traditional methods, Synchroextracting Transform (SET) algorithm can obtain the high-accuracy representation of a signal by energy distribution in time-frequency domain. Introducing SET algorithm to the pre-processing of fault signal can effectively realize the fault feature extraction and improve fault diagnosis performance. However, the model of classical SET algorithm consists of linear phase function and constant amplitude and has very strong limitation for a non-stationary signal with strong time-varying characteristics. The extracted fault feature can't well reflect fault representations in different time-frequency bands, which affects the accuracy of fault diagnosis.

The deep learning based fault identification model can transform the confused fault feature into a higher-dimension space to classify, which enhances the accuracy of fault diagnosis. In the regard of fault identification, convolutional neural network is a frequently-used deep learning architecture. However, convolutional neural network uses fixed sizes to perform fault feature extraction, and its perception range is limited. So it is difficult to obtain the key information of fault in the fault diagnosis of a RF front-end circuit, and the noise even possibly is taken as feature and transmitted to follow-up diagnosis, which lowers the accuracy of fault diagnosis.

### SUMMARY OF THE INVENTION

The present invention aims to overcome the deficiencies of the prior art, and provides a fault diagnosis method for the RF (Radio Frequency) front-end circuit of a MIMO (Multi-Input Multi-Output) system, so as to enhance fault representations in different time-frequency bands and improve the perception ability of fault identification model to key information of faults, thereby improving the accuracy of fault diagnosis.

To achieve these objectives, in accordance with the present invention, a fault diagnosis method for the RF front-end circuit of a MIMO system is provided, comprising:
(1). generating a fault test signal by an upper computer and transmitting the fault test signal to a RF front-end circuit of a MIMO system, then acquiring a fault signal s(t) from an output port of the RF front-end circuit, where t is time;
for a transmitting branch of the RF front-end circuit, the fault test signal is a sweeping signal with power p_{T} and frequency range f_{T1}˜f_{T2}, which is inputted to an input port of the transmitting branch, a fault signal s_{T}(t) acquired from an output port of the transmitting branch is the fault signal s(t), for a receiving branch of the RF front-end circuit, the fault test signal is a sweeping signal with power p_{R} and frequency range f_{R1}˜f_{R2}, which is inputted to an input port of the receiving branch, a fault signal s_{R}(t) acquired from an output port of the receiving branch is the fault signal s(t);
(2). using a Synchronous Enhancement Extracting Transform (hereinafter referred as SEET) to pre-process the acquired fault signal s(t) to extract fault feature components and obtain a real field two-dimensional matrix i and an imaginary field two-dimensional matrix q
2.1). creating a SEET operator \hat{ω}(t, ω):

$$ω ( t , ω ) = t - Img [ \frac{{𝒲}_{S}^{{G}^{″}} {𝒲}_{S}^{ω G} - {𝒲}_{S}^{{G}^{′}} {𝒲}_{S}^{ω {G}^{′}}}{{𝒲}_{S}^{G} {𝒲}_{S}^{ω {G}^{′}} - {𝒲}_{S}^{{G}^{′}} {𝒲}_{S}^{ω G}} ]$$

$$s . t . \vert {𝒲}_{S}^{G} {𝒲}_{S}^{ω {G}^{′}} - {𝒲}_{S}^{{G}^{′}} {𝒲}_{S}^{ω G} \vert > ε$$

where [symbol] _{S}^{G}, [symbol] _{S}^{G}′, [symbol] _{S}^{ωG}, [symbol] _{S}^{ωG}′ and [symbol] _{S}^{G}″ are time-frequency distributions obtained by performing short-time Fourier transforms on the acquired fault signal s(t) with window functions g(t), g′(t), tg(t), tg′(t) and g″(t) respectively, Img is a function of extracting the imaginary part of a complex number, s. t. is the abbreviation of “subject to”, ε is an error threshold;
2.2). performing a SEET: SEET(t, ω)= [symbol] _{S}^{G}(t, ω)·δ(ω−\hat{ω}(t, ω)), where δ(·) is Dirichlet function;
2.3). extracting fault feature components sₙ(t)|_{\hat{ω}}_{ₙ}_{(t,ω)}:

$${s}_{n} ( t ) {\vert}_{{\hat{ω}}_{n} ( t , ω )} = \frac{1}{2 π \hat{G} ( 0 )} {\int }_{{\hat{ω}}_{n} ( t , ω )} SEET ( t , ω ) {e}^{j ω t} d ω$$

where n is the serial number of a fault feature component of the fault signal s(t), n=1, 2, . . . , N, N is the total of fault feature components of the fault signal s(t), on \hat{ω}ₙ(t, ω) is the n^{th} component of the SEET operator \hat{ω}(t, ω), Ĝ(0) is a value of Fourier transform Ĝ(ω) of the window function g(t) at angular frequency ω=0;
2.4). calculating a real field feature iₙ(t)=Real[sₙ(t)|_{\hat{ω}}_{ₙ}_{(t,ω)}] and an imaginary field feature qₙ(t)=Img[sₙ(t)|_{\hat{ω}}_{ₙ}_{(t,ω)}] respectively according to fault feature components sₙ(t)|_{\hat{ω}}_{ₙ}_{(t,ω)}, n=1, 2, . . . , N, thus the real field two-dimensional matrix i and the imaginary field two-dimensional matrix q are obtained:

$$i = [ \begin{matrix}{i}_{1} ( {t}_{1} ) & {i}_{1} ( {t}_{2} ) & … & {i}_{1} ( {t}_{L - 1} ) & {i}_{1} ( {t}_{L} ) \\ {i}_{2} ( {t}_{1} ) & {i}_{2} ( {t}_{2} ) & … & {i}_{2} ( {t}_{L - 1} ) & {i}_{2} ( {t}_{L} ) \\ … & … & ⋱ & … & … \\ {i}_{N} ( {t}_{1} ) & {i}_{N} ( {t}_{2} ) & … & {i}_{N} ( {t}_{L - 1} ) & {i}_{N} ( {t}_{L} )\end{matrix} ]$$

$$q = [ \begin{matrix}{q}_{1} ( {t}_{1} ) & {q}_{1} ( {t}_{2} ) & … & {q}_{1} ( {t}_{L - 1} ) & {q}_{1} ( {t}_{L} ) \\ {q}_{2} ( {t}_{1} ) & {q}_{2} ( {t}_{2} ) & … & {q}_{2} ( {t}_{L - 1} ) & {q}_{2} ( {t}_{L} ) \\ … & … & ⋱ & … & … \\ {q}_{N} ( {t}_{1} ) & {q}_{N} ( {t}_{2} ) & … & {q}_{N} ( {t}_{L - 1} ) & {q}_{N} ( {t}_{L} )\end{matrix} ]$$

where iₙ(tₗ) and qₙ(tₗ) are the values of the n^{th} real field feature iₙ(t) and imaginary field qₙ(t) at time tₗ, l=1,2, . . . , L, respectively;
(3). creating a fault identification model fused by a complex field based asymmetric convolutional neural network and a complex field based multi-head attention module to perform fault identification
3.1). in the complex field based asymmetric convolutional neural network, performing convolutional samplings with a plurality of parallel branches on the real field two-dimensional matrix i to capture the detail features in vertical and horizontal directions, then perform scaling on the convolutional sampling result of each parallel branch, and then fusing the scaled convolutional sampling results of all parallel branches together to obtain a real field two-dimensional matrix i′, performing same convolutional samplings, scalings and fusing on the imaginary field two-dimensional matrix q to obtain an imaginary field two-dimensional matrix q′, lastly, multiplying the real field two-dimensional matrix i′ by trainable parameter matrices Wᵢ^{Q}, Wᵢ^{K} and Wᵢ^{V} to obtain a query matrix Qᵢ, a key matrix Kᵢ and a value matrix Vᵢ respectively, and multiplying the imaginary field two-dimensional matrix q′ by trainable parameter matrices W_{q}^{Q}, W_{q}^{K} and W_{q}^{V} to obtain a query matrix Q_{q}, a key matrix K_{q} and a value matrix V_{q} respectively;
3.2). in the complex field based multi-head attention module, firstly, dividing each of query matrix Qᵢ, key matrix Kᵢ, value matrix Vᵢ, query matrix Q_{q}, key matrix K_{q} and value matrix V_{q} into H matrices: Qᵢ^{(h)}, Kᵢ^{(h)}, Vᵢ^{(h)}, Q_{q}^{(h)}, K_{q}^{(h)} and V_{q}^{(h)}, h=0,1, . . . , H−1, thus obtaining H attention heads' query matrix Q^{(h)}, key matrix K^{(h)}, and value matrix V^{(h)}:

$${Q}^{( h )} = {Q}_{i}^{( h )} + {jQ}_{q}^{( h )}$$

$${K}^{( h )} = {K}_{i}^{( h )} + {jK}_{q}^{( h )}$$

$${V}^{( h )} = {V}_{i}^{( h )} + {jV}_{q}^{( h )} , h = 0 , 1 , … , H - 1$$

then calculating attention weight Attn^{(h)}=Attnᵢ^{(h)}+jAttn_{q}^{(h)} by the h^{th} attention head according to the h^{th} query matrix Q^{(h)}, key matrix K^{(h)}, and value matrix V^{(h)}, h=0,1,2, . . . H−1;
then fusing all attention weights together to obtain multi-head attention Attention:

$$Attention = {Attention}_{i} + {jAttention}_{q}$$

$$where :$$

$${Attention}_{i} = concat ( {Attn}_{i}^{( 0 )} , {Attn}_{i}^{( 1 )} , … , {Attn}_{i}^{( H - 1 )} )$$

$${Attention}_{q} = concat ( {Attn}_{q}^{( 0 )} , {Attn}_{q}^{( 1 )} , … , {Attn}_{q}^{( H - 1 )} )$$

where concat is a function of concatenating the data of the same dimension;
3.3). performing residual connection and outputting a distributed feature X:

$$X = {X}_{i} + {jX}_{q}$$

$$where :$$

$${X}_{i} = {Attention}_{i} + i$$

$${X}_{q} = {Attention}_{q} + q$$

3.4). obtaining corresponding fault status according to the distributed feature X;
(4). setting the network parameters of the fault identification model created by step (3), and training the fault identification model, then using the trained fault identification model to identify fault and obtain a fault status.

The objectives of the present invention are realized as follows:

To address the challenges in the fault diagnosis of the RF front-end circuit of a MIMO system and improve the accuracy of fault diagnosis, the present invention provides a fault diagnosis method for the RF front-end circuit of a MIMO system, which comprises using a SEET to pre-process the acquired fault signal to extract fault feature, creating a fault identification model fused by a complex field based asymmetric convolutional neural network and a complex field based multi-head attention module to assign fault feature wights, extract key feature and identify fault status. Wherein the step of using a SEET to pre-process the acquired fault signal to extract fault feature is applied with time-frequency analysis theory of compression and rearrangement and introduces Gaussian modulation chirp multiple-harmonic model to create a Synchronous Enhancement Extracting Transform (SEET) to extract fault feature components, and calculate its real field feature and imaginary field feature to obtain a real field two-dimensional matrix i and an imaginary field two-dimensional matrix q, thus an enhanced time-frequency feature is obtained. A complex field based asymmetric convolutional neural network and a complex field based multi-head attention module are introduced into the fault identification model, which is used for a transform from a complex field feature space to a high dimensional space and realizing the assignment of fault feature wights, key feature's extraction and fault status identification. The experimental results show that the present invention, a fault diagnosis method for RF front-end circuit of MIMO system can accurately extract the feature of a fault signal and accurately complete a fault diagnosis.

In addition, the present invention, a fault diagnosis method for the RF front-end circuit of a MIMO system also has the following advantages:
(1). The present invention has superior feature extraction and high efficiency fault identification, and only takes the input port and the output port of RF front-end circuit as the exciting point and test point respectively, thus there is no need to modify RF front-end circuit and increase test points, extra cost is avoided;
(2). The synchronous enhancement extracting transform (SEET) provided by the present invention can extract the high-resolution complex field feature from the fault signal, which has improved fault representations in different time-frequency bands, thereby improving the accuracy of fault diagnosis.
(3). The present invention creates a fault identification model, which is fused by a complex field based asymmetric convolutional neural network and a complex field based multi-head attention module to assign fault feature wights, extract key feature and identify fault status. The fault identification model can effectively take the local perception of asymmetric convolution and global feature weight dynamic assignment into account, which improves the perception of fault identification model to key fault information, and the fault identification model can extract the high dimensional feature from the fault signal, thus an accurate fault identification can be realized.

### BRIEF DESCRIPTION OF THE DRAWING

The above and other objectives, features and advantages of the present invention will be more apparent from the following detailed description taken in conjunction with the accompanying drawings, in which:

FIG. 1 is a flow chart of a fault diagnosis method for the RF front-end circuit of a MIMO system in accordance with one embodiment of the present invention.

FIG. 2 is a principle block diagram of fault diagnosis of the RF front-end circuit of a two-channel MIMO system in accordance with one embodiment of the present invention;

FIG. 3 is a flow chart of obtaining a real field two-dimensional matrix i and an imaginary field two-dimensional matrix q, which represent the fault feature of fault signal, by using a SEET;

FIG. 4 is a principle block diagram of a fault identification model fused by a complex field based asymmetric convolutional neural network and a complex field based multi-head attention module in accordance with one embodiment of the present invention, where (a) is the overall principle block diagram, (b) is the principle block diagram of the complex field based asymmetric convolutional neural network, (c) is the principle block diagram of complex field based multi-head attention module;

FIG. 5 is a flow chart of creating a fault identification model fused by a complex field based asymmetric convolutional neural network and a complex field based multi-head attention module to perform fault identification in accordance with one embodiment of the present invention;

FIG. 6 is a flow chart of the asymmetric convolution in a complex field based asymmetric convolutional neural network in accordance with one embodiment of the present invention;

FIG. 7 is a flow chart of calculating a multi-head attention through a complex field based multi-head attention module in accordance with the present invention;

FIG. 8(a)˜FIG. 8(b) are training effect illustrations of a fault identification model fused by a complex field based asymmetric convolutional neural network and a complex field based multi-head attention module in accordance with the present invention, where FIG. 8(a) is a training effect drawing of a fault identification model for a transmitting branch, which includes a training accuracy curve and a loss curve, FIG. 8(b) is a training effect drawing of a fault identification model for a receiving branch, which includes a training accuracy curve and a loss curve;

FIG. 9(a)˜FIG. 9(b) are testing effect illustrations of a fault identification model fused by a complex field based asymmetric convolutional neural network and a complex field based multi-head attention module in accordance with the present invention, where FIG. 9(a) is a confusion matrix of a transmitting branch, FIG. 9(b) is a confusion matrix of a receiving branch.

FIG. 10(a)˜FIG. 10(b) are effect illustrations of a fault diagnosis method for RF front-end circuit of MIMO system in accordance with the present invention, where FIG. 10(a) is a feature classification illustration of a transmitting branch, where FIG. 10(b) is a feature classification illustration of a receiving branch.

### DETAILED DESCRIPTION OF THE PREFERRED EMBODIMENT

Hereinafter, preferred embodiments of the present invention will be described with reference to the accompanying drawings. It should be noted that the similar modules are designated by similar reference numerals although they are illustrated in different drawings. Also, in the following description, a detailed description of known functions and configurations incorporated herein will be omitted when it may obscure the subject matter of the present invention.

The present invention improves the fault diagnosis method for the RF front-end circuit of a MIMO system from two aspects: fault feature extraction based on time-frequency analysis technology and fault identification model based on deep learning. In the fault feature extraction, a Gaussian modulation chirp multiple-harmonic model is introduced to remodel the fault signal of the RF front-end circuit, and a time-frequency analysis technology based on synchronous enhancement extracting transform is used to pre-process the fault signal and extract the complex field feature from the fault signal, the complex field feature is taken as the fault feature, thus the time-frequency feature of a fault feature is enhanced. In fault identification model, a deep learning architecture fused by a complex field based asymmetric convolutional neural network and a complex field based multi-head attention module are introduced, which is used for transforming the complex field feature of the fault signal to a high dimensional space, through the complex field asymmetric convolution's local perception and multi-head attention module's global feature weight dynamic assignment, the perception of fault identification model to key fault information is improved, and the fault identification model can extract the high dimensional feature from the fault signal, thus an accurate fault identification can be realized.

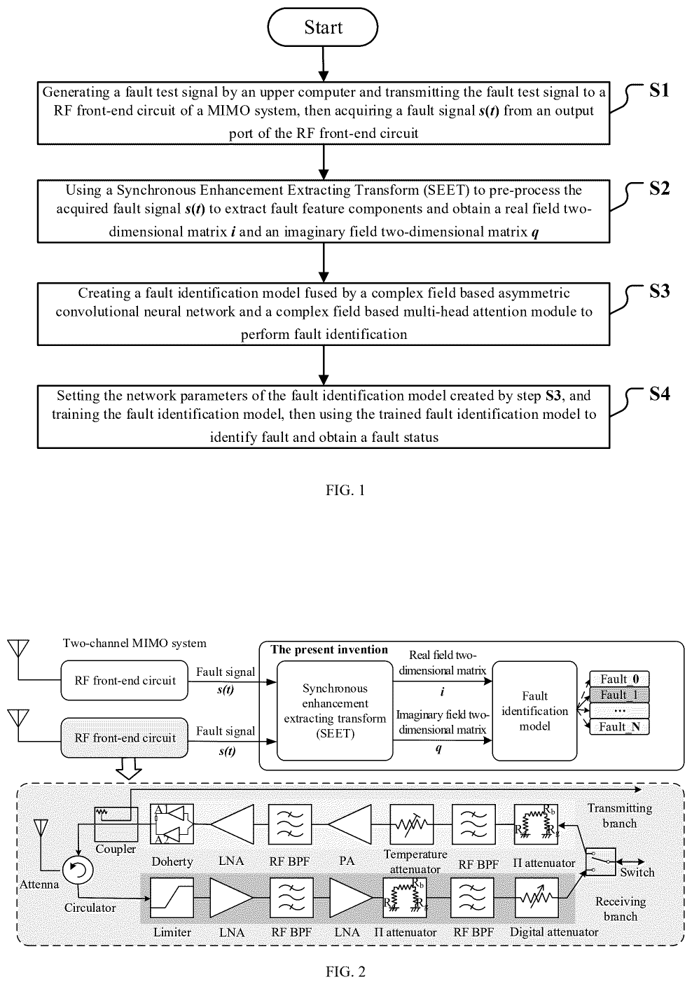

FIG. 1 is a flow chart of a fault diagnosis method for the RF front-end circuit of a MIMO system in accordance with one embodiment of the present invention.

As shown in FIG. 1, the present invention, a fault diagnosis method for the RF front-end circuit of a MIMO system comprises the following steps:

Step S1: generating a fault test signal by an upper computer and transmitting the fault test signal to a RF front-end circuit of a MIMO system, then acquiring a fault signal s(t) from an output port of the RF front-end circuit, where t is time.

For a transmitting branch of the RF front-end circuit, the fault test signal is a sweeping signal with power p_{T} and frequency range f_{T1}˜f_{T2}, which is inputted to an input port of the transmitting branch, a fault signal s_{T}(t) acquired from an output port of the transmitting branch is the fault signal s(t), for a receiving branch of the RF front-end circuit, the fault test signal is a sweeping signal with power pp and frequency range f_{R1}˜f_{R2}, which is inputted to an input port of the receiving branch, a fault signal s_{R}(t) acquired from an output port of the receiving branch is the fault signal s(t).

In one embodiment, the MIMO system is a two-channel MIMO system. As shown in FIG. 2, each RF front-end circuit of the two-channel MIMO system includes a transmitting branch and a receiving branch, wherein:

The transmitting branch is responsible for amplifying a low-power modulated signal to a sufficiently high-power level to meet the requirement of radar communication. Therefore, it mainly consists of a Doherty amplifier, a power amplifier, a linear amplifier, a RF bandpass filter (RF BPF) used to improve signal quality and an attenuator.

The receiving branch is responsible for amplifying and filtering a weak and noisy signal to meet the requirements of signal processing. Therefore, it mainly consists of a limiter, a low-noise amplifier (LNA) and circuit devices such as RF bandpass filter (RF BPF) and attenuator used to improve signal quality and achieve impedance matching.

In one embodiment, the fault test signal of the transmitting branch is a linear sweeping signal with power p_{T}=−45 dBm and frequency range f_{T1}: 1990 MHz˜f_{T2}: 2100 MHz, the fault test signal of the receiving branch is a linear sweeping signal with power p_{R}=−35 dBm and frequency range f_{R1}: 1990 MHz˜f_{R2}: 2100 MHz.

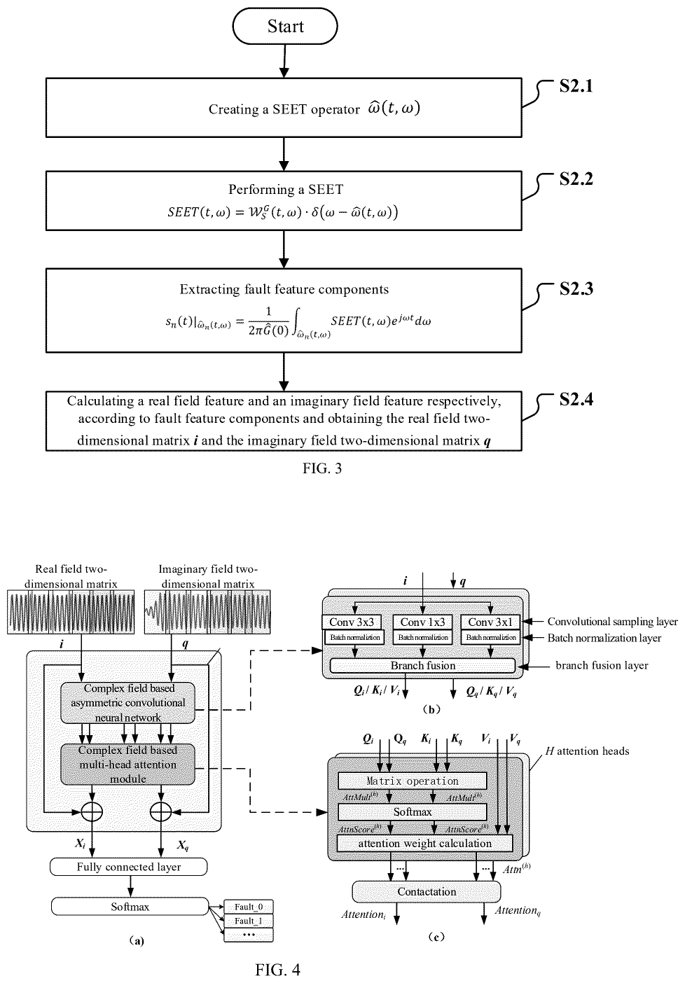

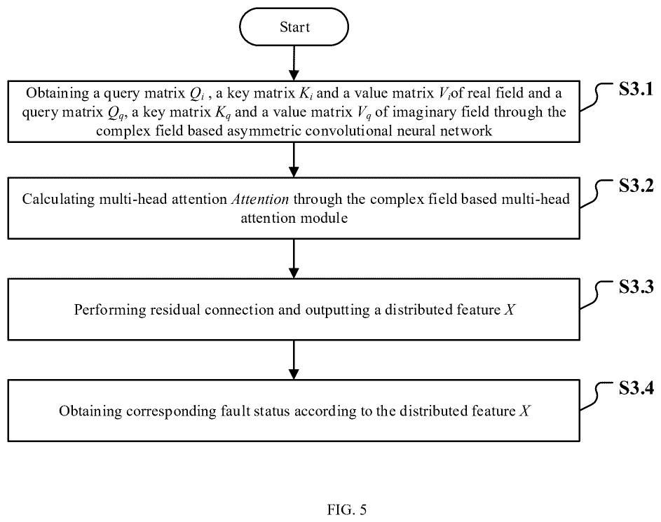

Step S2: using a Synchronous Enhancement Extracting Transform (SEET) to pre-process the acquired fault signal s(t) to extract fault feature components and obtain a real field two-dimensional matrix i and an imaginary field two-dimensional matrix q. In one embodiment, as shown in FIG. 3, step S2 further comprises the follows steps:

Step S2.1: creating a SEET operator \hat{ω}(t, ω):

$$ω ( t , ω ) = t - Img [ \frac{{𝒲}_{S}^{{G}^{″}} {𝒲}_{S}^{ω G} - {𝒲}_{S}^{{G}^{′}} {𝒲}_{S}^{ω {G}^{′}}}{{𝒲}_{S}^{G} {𝒲}_{S}^{ω {G}^{′}} - {𝒲}_{S}^{{G}^{′}} {𝒲}_{S}^{ω G}} ] \qquad ( 1 )$$

$$s . t . \vert {𝒲}_{S}^{G} {𝒲}_{S}^{ω {G}^{′}} - {𝒲}_{S}^{{G}^{′}} {𝒲}_{S}^{ω G} \vert > ε$$

where [symbol] _{S}^{G}, [symbol] _{S}^{G}′, [symbol] _{S}^{ωG}, [symbol] _{S}^{ωG}′ and [symbol] _{S}^{G}″ are time-frequency distributions obtained by performing short-time Fourier transforms with window functions g(t), g′(t), tg(t), tg′(t) and g″(t) respectively, Img is a function of extracting the imaginary part of a complex number, s. t. is the abbreviation of “subject to”, ε is an error threshold.

The complex field representation of the fault signal s(t) can be written as s(t)=A(t)e^{jφ(t)}. To better characterize the time-varying property of the fault signal s(t), a Gaussian modulation chirp multiple-harmonic model is introduced to remodel the fault signal, thus the Fourier transform of the fault signal can be expressed as follows:

$${S}_{G} ( ω ) = A ( ω ) {e}^{j φ ( ω )} = {Ae}^{- \frac{{( ω - {ω}_{0} )}^{2}}{2 {S}^{2}}} \cdot {e}^{j \cdot ( a + b ω + \frac{1}{2} c {ω}^{2} )} \qquad ( 2 )$$

where A, ω₀ and s are the amplitude of the fault signal, the central frequency of the fault signal and a constant respectively, a, b, c are the binomial coefficients of the fault signal's angular frequency. The instantaneous frequency of the fault signal can be expressed as φ′(ω)=b+cω.

For the fault signal s(t) has N components, namely s(t)=Σₙ₌₁^{N}sₙ(t)=Σₙ₌₁^{N}Aₙ(t)e^{jφ}^{ₙ}^{(t)}, the ideal time-frequency representation (ITFR) can be expressed as ITFR(t, ω)=Σₙ₌₁^{N}Aₙ(t)e^{jφ}^{ₙ}^{(t)}δ(ω−φₙ′(t)), where δ(·) is Dirichlet function.

In an ideal situation, we hope the Fourier transform of window function g(t) meets: Ĝ(ω)=δ(ω), which means g(t)=1. But in a real situation, g(t)=1 is conflict with the requirements of strong time-varying application scenarios, which leads to spectral ambiguity, a better frequency resolution can't be obtained. Therefore, no matter how we choose the window function of Fourier transform, we cannot achieve the ideal time-frequency representation.

According to time frequency rearrangement theory, the time-frequency ridge line is the curve in the time-frequency distribution of a signal that represents the local maximum intensity of the signal, and therefore can be used as an ideal time-frequency representation of the signal. The time-frequency ridge line can be determined by solving the maximum instantaneous frequency and concavity of the fault signal. The detail steps are as follow:

Calculating the time-frequency distribution of the fault signal by short-time Fourier transform according to Parseval's theorem:

$$( 3 )$$

$${𝒲}_{S}^{G} ( t , ω ) = {\int }_{- ∞}^{∞} s ( τ ) \cdot \hat{g} ( τ - t ) {e}^{- j ω ( τ - t )} d τ = \frac{1}{2 π} {\int }_{- ∞}^{∞} S ( v ) \cdot \hat{G} ( v - ω ) {e}^{j ( v - ω ) t} dv$$

where ĝ(t) is the conjugate of window function g(t);

Calculating the maximum instantaneous frequency of the fault signal: firstly, calculating the partial derivative of the time-frequency distribution [symbol] _{S}^{G}(t, ω) with respect to frequency:

$$\frac{\partial }{\partial ω} {𝒲}_{S}^{G} ( t , ω ) = \frac{1}{2 π} {\int }_{- ∞}^{∞} S ( v ) \cdot \hat{G} ( v - ω ) {e}^{j ( v - ω ) t} dv = \frac{1}{2 π} {\int }_{- ∞}^{∞} \frac{\partial }{\partial ω} [ Ae \frac{{( v - {ω}_{0} )}^{2}}{2 {s}^{2}} \cdot {e}^{j ( a + bv + \frac{1}{2} {cv}^{2} )} ] \cdot \hat{G} ( v - ω ) {e}^{j ( v - ω ) t} dv = \frac{1}{2 π} {\int }_{- ∞}^{∞} ( ( - \frac{1}{{s}^{2}} + jc ) ω + ( \frac{{ω}_{0}}{{s}^{2}} + jb ) ) S ( v ) \cdot \hat{G} ( v - ω ) {e}^{j ( v - ω ) t} dv$$

Then letting η=−1/s²+jc, Σ=ω₀/s²+j, we can obtain:

$$- {W}_{S}^{{G}^{′}} ( t , ω ) = ( η ω + ρ ) {W}_{S}^{G} ( t , ω ) + ρ {W}_{S}^{ω G} ( t , ω ) \qquad ( 5 )$$

Calculating the shape of the time-frequency ridge line: calculating the second partial derivative of [symbol] _{S}^{G}′(t, ω) with respect to frequency to obtain the concavity of instantaneous frequency:

$$- {W}_{S}^{{G}^{′′}} ( t , ω ) = ( η ω + ρ + jt ) {W}_{S}^{{G}^{′}} ( t , ω ) + ρ {W}_{S}^{ω {G}^{′}} ( t , ω ) \qquad ( 6 )$$

Considering ηω+ρ and ρ as solutions to formulas (5) and (6) respectively, we can obtain:

$$\{ \begin{matrix}ηω + ρ = - jt + \frac{{W}_{S}^{{G}^{′′}} {W}_{S}^{ω G} - {W}_{S}^{{G}^{′}} {W}_{S}^{ω {G}^{′}}}{{W}_{S}^{G} {W}_{S}^{ω {G}^{′}} - {W}_{S}^{{G}^{′}} {W}_{S}^{ω G}} \\ ρ = \frac{{( {W}_{S}^{{G}^{′}} )}^{2} - {W}_{S}^{{G}^{′′}} {W}_{S}^{G}}{{W}_{S}^{G} {W}_{S}^{ω {G}^{′}} - {W}_{S}^{{G}^{′}} {W}_{S}^{ω G}}\end{matrix} \qquad ( 7 )$$

where [symbol] _{S}^{G}, [symbol] _{S}^{G}′, [symbol] _{S}^{ωG}, [symbol] _{S}^{ωG}′ and [symbol] _{S}^{G}″ are time-frequency distributions obtained by performing short-time Fourier transforms on the fault signal s(t) with window functions g(t), g′(t), tg(t), tg′(t) and g″(t) respectively.

According to fault signal model: φ′(ω)=b+cω=Imag[ηω+ρ], substituting formula (7), the estimated time-frequency ridge is derived as:

$$\hat{ω} ( t , ω ) = {φ}^{′} ( ω ) = t - Img [ \frac{{W}_{S}^{{G}^{′′}} {W}_{S}^{ω G} - {W}_{S}^{{G}^{′}} {W}_{S}^{ω {G}^{′}}}{{W}_{S}^{G} {W}_{S}^{ω {G}^{′}} - {W}_{S}^{{G}^{′}} {W}_{S}^{ω G}} ] \qquad ( 8 )$$

$$s . t . \vert {W}_{S}^{G} {W}_{S}^{ω {G}^{′}} - {W}_{S}^{{G}^{′}} {W}_{S}^{ω G} \vert > ε$$

where Img is a function of extracting the imaginary part of a complex number, s. t. is the abbreviation of “subject to”, ε is an error threshold.

Therefore, the time-frequency ridge represented by, \hat{ω}(t, ω) is the ideal time-frequency representation (ITFR) of the fault signal s(t).

Step S2.2: performing a SEET: SEET(t, ω)= [symbol] _{S}^{G}(t, ω)·δ(ω−\hat{ω}(t, ω)), where δ(·) is Dirichlet function.

Step S2.3: extracting fault feature components sₙ(t)|_{\hat{ω}}_{ₙ}_{(t,ω)}:

$${s}_{n} ( t ) {\vert}_{{\hat{ω}}_{n} ( t , ω )} = \frac{1}{2 π \hat{G} ( 0 )} {\int }_{{\hat{ω}}_{n} ( t , ω )} SEET ( t , ω ) {e}^{j ω t} d ω \qquad ( 9 )$$

where n is the serial number of a fault feature component of the fault signal s(t), n=1, 2, . . . , N, N is the total of fault feature components of the fault signal s(t), \hat{ω}ₙ(t, ω) is the n^{th} component of the SEET operator \hat{ω}(t, ω), Ĝ(0) is a value of Fourier transform Ĝ(ω) of the window function g(t) at angular frequency ω=0.

According to s(t)=Σₙ₌₁^{N}Aₙ(t)e^{jφ}^{ₙ}^{(t)}, there is \hat{ω}(t, ω)=Σₙ₌₁^{N}\hat{ω}ₙ(t, ω). Therefore, after performing a SEET, the time-frequency distribution represented by SEET(t, ω) contains fault feature components sₙ(t)|_{\hat{ω}}_{ₙ}_{(t,ω)}:

$$\begin{matrix}SEET ( t , ω ) = {W}_{S}^{G} ( t , ω ) \cdot δ ( ω - \hat{ω} ( t , ω ) ) = {W}_{S}^{G} ( t , ω ) {\vert}_{t - {\sum }_{n = 1}^{N} {\hat{ω}}_{n} ( t , ω ) = 0} \\ = {\sum }_{n = 1}^{N} {\hat{A}}_{n} ( ω ) \cdot \hat{G} ( 0 ) \cdot {e}^{j {\hat{ω}}_{n} ( ω )} = {\sum }_{n = 1}^{N} {S}_{n} ( t , {\hat{ω}}_{n} ( t , ω ) )\end{matrix} \qquad ( 10 )$$

Performing time-domain reconstruction on the fault feature components, and according to the inverse Fourier transform, we can obtain:

$${s}_{n} ( t ) {\vert}_{{\hat{ω}}_{n} ( t , ω )} = \frac{1}{2 π \hat{G} ( 0 )} {\int }_{{\hat{ω}}_{n} ( t , ω )} SEET ( t , ω ) {e}^{j ω t} d ω \qquad ( 11 )$$

Step S2.4: calculating a real field feature iₙ(t)=Real[sₙ(t)|_{\hat{ω}}_{ₙ}_{(t,ω)}] and an imaginary field feature qₙ(t)=Img[sₙ(t)|_{\hat{ω}}_{ₙ}_{(t,ω)}] respectively according to fault feature components sₙ(t)|_{\hat{ω}}_{ₙ}_{(t,ω)}, n=1, 2, . . . , N, thus the real field two-dimensional matrix i and the imaginary field two-dimensional matrix q are obtained:

$$i = [ \begin{matrix}{i}_{1} ( {t}_{1} ) & {i}_{1} ( {t}_{2} ) & ⋯ & {i}_{1} ( {t}_{L - 1} ) & {i}_{1} ( {t}_{L} ) \\ {i}_{2} ( {t}_{1} ) & {i}_{2} ( {t}_{2} ) & ⋯ & {i}_{2} ( {t}_{L - 1} ) & {i}_{2} ( {t}_{L} ) \\ ⋯ & ⋯ & ⋱ & ⋯ & ⋯ \\ {i}_{N} ( {t}_{1} ) & {i}_{N} ( {t}_{2} ) & ⋯ & {i}_{N} ( {t}_{L - 1} ) & {i}_{N} ( {t}_{L} )\end{matrix} ] \qquad ( 12 )$$

$$q = [ \begin{matrix}{q}_{1} ( {t}_{1} ) & {q}_{1} ( {t}_{2} ) & ⋯ & {q}_{1} ( {t}_{L - 1} ) & {q}_{1} ( {t}_{L} ) \\ {q}_{2} ( {t}_{1} ) & {q}_{2} ( {t}_{2} ) & ⋯ & {q}_{2} ( {t}_{L - 1} ) & {q}_{2} ( {t}_{L} ) \\ ⋯ & ⋯ & ⋱ & ⋯ & ⋯ \\ {q}_{N} ( {t}_{1} ) & {q}_{N} ( {t}_{2} ) & ⋯ & {q}_{N} ( {t}_{L - 1} ) & {q}_{N} ( {t}_{L} )\end{matrix} ] \qquad ( 13 )$$

where iₙ(tₗ) and qₙ(tₗ) are the values of the n^{th} real field feature iₙ(t) and imaginary field qₙ(t) at time tₗ, l=1,2, . . . , L, respectively.

In one embodiment, the length of the fault signal is L=2050, the number of the fault feature components is N=3, namely, after performing a SEET, we obtain 3 fault feature components, from each fault feature component, we can extract two feature vectors of length 2050 in real field and imaginary field respectively. Therefore, the size of the real field two-dimensional matrix i and the imaginary field two-dimensional matrix q is 3×2050.

Step S3: creating a fault identification model fused by a complex field based asymmetric convolutional neural network and a complex field based multi-head attention module to perform fault identification.

In one embodiment, the fault identification model comprises a complex field based asymmetric convolutional neural network and a complex field based multi-head attention module. Where as shown in part (a) of FIG. 4, the complex field based asymmetric convolutional neural network transforms the extracted the real field two-dimensional matrix i and the imaginary field two-dimensional matrix q respectively into a query matrix, a key matrix and a value matrix; through attention score calculation, weight calculation and multi-head fusion calculation, the complex field based multi-head attention realizes global feature weight dynamic assignment and key feature extraction.

In one embodiment, as shown in FIG. 5, creating a fault identification model fused by a complex field based asymmetric convolutional neural network and a complex field based multi-head attention module to perform fault identification comprises the following steps:

Step S3.1: obtaining a query matrix Qᵢ, a key matrix Kᵢ and a value matrix Vᵢ of real field and a query matrix Q_{q}, a key matrix K_{q} and a value matrix V_{q} of imaginary field through the complex field based asymmetric convolutional neural network.

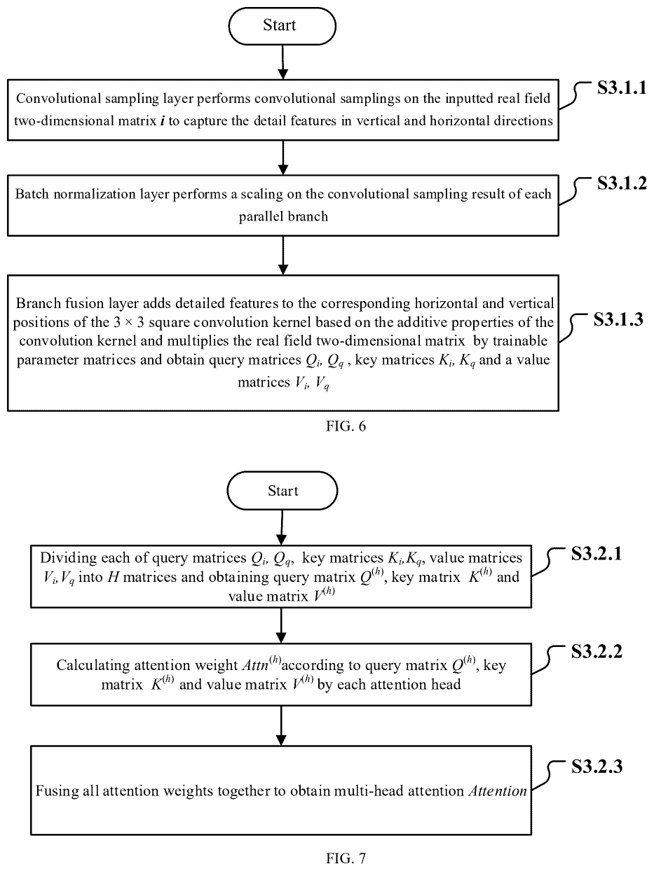

In the complex field based asymmetric convolutional neural network, performing convolutional samplings with a plurality of parallel branches on the real field two-dimensional matrix i to capture the detail features in vertical and horizontal directions, then perform scaling on the convolutional sampling result of each parallel branch, and then fusing the scaled convolutional sampling results of all parallel branches together to obtain a real field two-dimensional matrix i′, performing same convolutional samplings, scalings and fusing on the imaginary field two-dimensional matrix q to obtain an imaginary field two-dimensional matrix q′, lastly, multiplying the real field two-dimensional matrix i′ by trainable parameter matrices Wᵢ^{Q}, Wᵢ^{K} and Wᵢ^{V} to obtain a query matrix Qᵢ, a key matrix Kᵢ and a value matrix Vᵢ respectively, and multiplying the imaginary field two-dimensional matrix q′ by trainable parameter matrices W_{q}^{Q}, W_{q}^{K} and W_{q}^{V} to obtain a query matrix Q_{q}, a key matrix K_{q} and a value matrix V_{q} respectively. Specifically, as shown in part (b) of FIG. 4, the complex field based asymmetric convolutional neural network includes a convolutional sampling layer, a batch normalization layer and a branch fusion layer. As show in FIG. 6, The functions and operations involved in each layer include the following steps:

Step S3.1.1: the convolutional sampling layer uses convolutional kernels Conv 3×3, Conv 1×3 and Conv 3×1 to perform convolutional samplings on the inputted real field two-dimensional matrix i respectively, so as to capture the detail features in vertical and horizontal directions. The operation results of the convolutional sampling layer are W^{3×3}, W^{1×3} and W^{3×1} the corresponding convolution kernels are denoted as k^{3×3}, k^{1×3} and k^{3×1} and the convolution operation is denoted as ⊗, we can obtain:

$${W}^{3 \times 3} = {k}^{3 \times 3} ⊗ i , \qquad ( 14 )$$

$${W}^{1 \times 3} = {k}^{1 \times 3} ⊗ i ,$$

$${W}^{3 \times 1} = {k}^{3 \times 1} ⊗ i$$

Step S3.1.2: the batch normalization layer performs a scaling on the convolutional sampling result of each parallel branch. According to the principle of batch normalization and linear scaling transformation, the expectations for the parallel branches are denoted as μ^{3×3}, μ^{1×3} and μ^{3×1} respectively, the scale factors for the parallel branches are denoted as

$$\frac{{λ}^{3 \times 3}}{{σ}^{3 \times 3}} , \frac{{λ}^{1 \times 3}}{{σ}^{1 \times 3}} and \frac{{λ}^{3 \times 1}}{{σ}^{3 \times 1}}$$

respectively, the errors for the parallel branches are denoted as ξ^{3×3}, ξ^{1×3} and ξ^{3×1} respectively, the operation results of the batch normalization layer are denoted as W′^{3×3}, W′^{1×3} and W′^{3×1} respectively, then we can obtain:

$${W}^{′3 \times 3} = \frac{{λ}^{3 \times 3}}{{σ}^{3 \times 3}} \cdot ( {W}^{3 \times 1} - {μ}^{3 \times 3} ) + {ξ}^{3 \times 3} \qquad ( 15 )$$

$${W}^{′1 \times 3} = \frac{{λ}^{1 \times 3}}{{σ}^{1 \times 3}} \cdot ( {W}^{1 \times 3} - {μ}^{1 \times 3} ) + {ξ}^{1 \times 3}$$

$${W}^{′3 \times 1} = \frac{{λ}^{3 \times 1}}{{σ}^{3 \times 1}} \cdot ( {W}^{3 \times 1} - {μ}^{3 \times 1} ) + {ξ}^{3 \times 1}$$

Step S3.1.3: firstly, the branch fusion layer adds detailed features to the corresponding horizontal and vertical positions of the 3×3 square convolution kernel based on the additive properties of the convolution kernel, achieving branch fusion and obtaining a real field two-dimensional matrix i′:

$${i}^{′} = {W}^{′3 \times 3} ⊕ {W}^{′1 \times 3} ⊕ {W}^{′3 \times 1} \qquad ( 16 )$$

where ⊕ is a branch fusion operation.

The batch normalization layer performs the same convolutional samplings, scalings and fusing on the imaginary field two-dimensional matrix q to obtain an imaginary field two-dimensional matrix q′ according to steps S3.1.1˜S3.1.3.

Then, the branch fusion layer multiplies the real field two-dimensional matrix i′ by trainable parameter matrices Wᵢ^{Q}, Wᵢ^{K} and Wᵢ^{V} to obtain a query matrix Qᵢ, a key matrix Kᵢ and a value matrix Vᵢ respectively, and multiplies the imaginary field two-dimensional matrix q′ by trainable parameter matrices W_{q}^{Q}, W_{q}^{K} and W_{q}^{V} to obtain a query matrix Q_{q}, a key matrix K_{q} and a value matrix V_{q} respectively.

Step S3.2: calculating multi-head attention Attention through the complex field based multi-head attention module

In one embodiment, as shown in part (c) of FIG. 4), the complex field based multi-head attention module is obtained by modifying the structure of multi-head self-attention (MHSA), intending to represent each feature sequence by the weighted sum of complex field features. After obtaining matrices Qᵢ, Q_{q}, Kᵢ, K_{q}, Vᵢ and V_{q}, the complex field based multi-head attention module performs attention score calculation, weight calculation and multi-head fusion in sequence. As shown in FIG. 7, the operations involved in these processes are as follows:

Step S3.2.1: in the complex field based multi-head attention module, firstly, dividing each of query matrix Qᵢ, key matrix Kᵢ, value matrix Vᵢ, query matrix Q_{q}, key matrix K_{q} and value matrix V_{q} into H matrices: Qᵢ^{(h)}, Kᵢ^{(h)}, Vᵢ^{(h)}, Q_{q}^{(h)}, K_{q}^{(h)} and V_{q}^{(h)}, h=0,1, . . . , H−1, thus obtaining H attention heads' query matrix Q^{(h)}, key matrix K^{(h)}, and value matrix V^{(h)}:

$${Q}^{( h )} = {Q}_{i}^{( h )} + {jQ}_{q}^{( h )} , {K}^{( h )} = {K}_{i}^{( h )} + {jK}_{q}^{( h )} , {V}^{( h )} = {V}_{i}^{( h )} + {jV}_{q}^{( h )} , h = 0 , 1 , … , H - 1 \qquad ( 17 )$$

Step S3.2.2: then calculating attention weight Attn^{(h)}=Attnᵢ^{(h)}+jAttn_{q}^{(h)} by the h^{th} attention head according to the h^{th} query matrix Q^{(h)}, key matrix K^{(h)}, and value matrix V^{(h)}, h=0,1,2, . . . H−1. Specifically, this step comprises the following substeps:

Calculating attention scores: according to scale dot-product attention formula, the attention score of the h^{th} attention head is AttnScore^{(h)}=softmax(Q^{(h)}K^{(h)}^{^{T}}/\sqrt{d_{ρ}})V^{(h)}. Therefore, the matrix operation in softmax function is:

$$\begin{matrix}AttnMult ( {Q}^{( h )} , {K}^{( h )} ) = \frac{{Q}^{( h )} , {K}^{{( h )}^{T}}}{\sqrt{{d}_{ρ}}} \\ = ( {Q}_{i}^{( h )} + j {Q}_{q}^{( h )} ) {( {K}_{i}^{( h )} + {jK}_{q}^{( h )} )}^{T} / \sqrt{{d}_{ρ}} \\ = ( {Q}_{i}^{( h )} {K}_{i}^{{( h )}^{T}} + {Q}_{q}^{( h )} {K}_{q}^{{( h )}^{T}} ) / \sqrt{{d}_{ρ}} \\ + j ( {Q}_{q}^{( h )} {K}_{i}^{{( h )}^{T}} + {Q}_{i}^{( h )} {K}_{q}^{{( h )}^{T}} ) / \sqrt{{d}_{q}}\end{matrix} \qquad ( 18 )$$

letting AttnMultᵢ^{(h)}=(Qᵢ^{(h)}Kᵢ^{(h)}^{^{T}}−Q_{q}^{(h)}K_{q}^{(h)}^{^{T}})/\sqrt{d_{ρ}}, AttnMult_{q}^{(h)}=(Q_{q}^{(h)}Kᵢ^{(h)}^{^{T}}−Qᵢ^{(h)}K_{q}^{(h)}^{^{T}})/\sqrt{d_{ρ}}, then the attention scores of the h^{th} attention head are:

$${AttnScore}_{i}^{( h )} = softmax ( {AttnMult}_{i}^{( h )} ) \qquad ( 19 )$$

$${AttnScore}_{q}^{( h )} = softmax ( {AttnMult}_{q}^{( h )} )$$

Calculating an attention weight: multiplying the attention scores by value matrix, then each attention weight can be obtained, the processes of calculating an attention weight are as follows:

$${Attn}^{( h )} = ( {AttnScore}_{i}^{( h )} + {jAttnScore}_{q}^{( h )} ) {( {V}_{i}^{( h )} + {jV}_{q}^{( h )} )}^{T} = ( {AttnScore}_{i}^{( h )} {V}_{i}^{{( h )}^{T}} - {AttnScore}_{q}^{( h )} {V}_{q}^{{( h )}^{T}} ) + j ( {AttnScore}_{i}^{( h )} {V}_{q}^{{( h )}^{T}} + {AttnScore}_{q}^{( h )} {V}_{i}^{{( h )}^{T}} ) \qquad ( 20 )$$

$${Attn}_{i}^{( h )} = {AttnScore}_{i}^{( h )} {V}_{i}^{{( h )}^{T}} - {AttnScore}_{q}^{( h )} {V}_{q}^{{( h )}^{T}}$$

$${Attn}_{q}^{( h )} = {AttnScore}_{i}^{( h )} {V}_{q}^{{( h )}^{T}} + {AttnScore}_{q}^{( h )} {V}_{i}^{{( h )}^{T}}$$

The obtained attention weight is Attn^{(h)}=Attnᵢ^{(h)}+jAttn_{q}^{(h)}.

Step S3.2.3: then fusing all attention weights together to obtain multi-head attention Attention:

$$Attention = {Attention}_{i} + {jAttention}_{q} \qquad ( 21 )$$

$$where :$$

$${Attention}_{i} = concat ( {Attn}_{i}^{( 0 )} , {Attn}_{i}^{( 1 )} , … , {Attn}_{i}^{( H - 1 )} ) \qquad ( 22 )$$

$${Attention}_{q} = concat ( {Attn}_{q}^{( 0 )} , {Attn}_{q}^{( 1 )} , … , {Attn}_{q}^{( H - 1 )} )$$

where concat is a function of concatenating the data of the same dimension;

Step S3.3: performing residual connection and outputting a distributed feature X:

$$X = {X}_{i} + {jX}_{q} \qquad ( 23 )$$

$$where :$$

$${X}_{i} = {Attention}_{i} + i , {X}_{q} = {Attention}_{q} + q$$

Step S3.4: obtaining corresponding fault status according to the distributed feature X;

In one embodiment, as shown in part (a) of FIG. 4, the probability of each fault status can be obtained by passing the distributed feature X through a fully connected layer and then using Softmax function. The fault status with the highest probability is the corresponding fault status obtained from the distributed feature X. Obtaining a corresponding category based on a distributed feature belongs to the prior art, and will not be further elaborated here. In one embodiment, the dimension parameter selected for the fully connected layer is 512, and the number of the fault statuses is 14.

Step S4: setting the network parameters of the fault identification model created by step S3, and training the fault identification model, then using the trained fault identification model to identify fault and obtain a fault status. Specifically, this step includes:

Firstly, performing fault mode and effect analysis on the RF front-end circuit of a MIMO system to obtain all fault statuses, and acquiring a fault signal for each fault status according to step S1, then extracting fault feature according to step S2 to obtain a training set, then using the training set to train the fault identification model;

Then, obtaining a fault feature according to the methods of steps S1 and S2, and sending the fault feature to the fault identification model trained in step S4 to obtain a corresponding fault status.

In one embodiment, a FMEA fault analysis is performed on the RF front-end circuit of the two-channel MIMO system in FIG. 1, and the fault statuses and corresponding fault labels of the transmitting branch and receiving branch are obtained and shown in Table 1:

TABLE 1

| Transmitting branch | | | Receiving branch | | |
|---|---|---|---|---|---|
| Fault | Fault status | | Fault | Fault status | |
| label | Component | Status | label | Component | Status |
| T0 | All | Healthy | R0 | All | Healthy |
| T1 | Π attenuator -R_{b} | Short | R1 | Π attenuator -R_{b} | Short |
| T2 | Π attenuator r-R_{b} | Open | R2 | Π attenuator -R_{b} | Open |
| T3 | Π attenuator -R_{g} | Short | R3 | Π attenuator -R_{b} | Drifted |
| T4 | Π attenuator -R_{g} | Open | R4 | Π attenuator -R_{g} | Short |
| T5 | RF BPF | Drifted | R5 | Π attenuator -R_{g} | Open |
| T6 | Power amplifier | Drifted | R6 | Π attenuator -R_{g} | Drifted |
| T7 | RF BPF | Drifted | R7 | RF BPF | Drifted |
| T8 | Linear amplifier | Open | R8 | Power amplifier | Drifted |
| T9 | Doherty-A1 | Open | R9 | LNA | Drifted |
| T10 | Doherty-A2 | Drifted | R10 | LNA | Drifted |
| T11 | Doherty | Open | R11 | LNA | Open |
| T12 | Circulator | Drifted | R12 | Limiter | Open |
| T13 | Circulator | Drifted | R13 | Digital attenuator | Drifted |

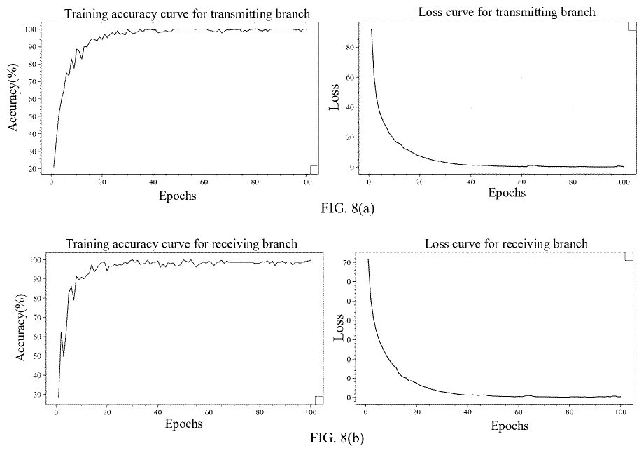

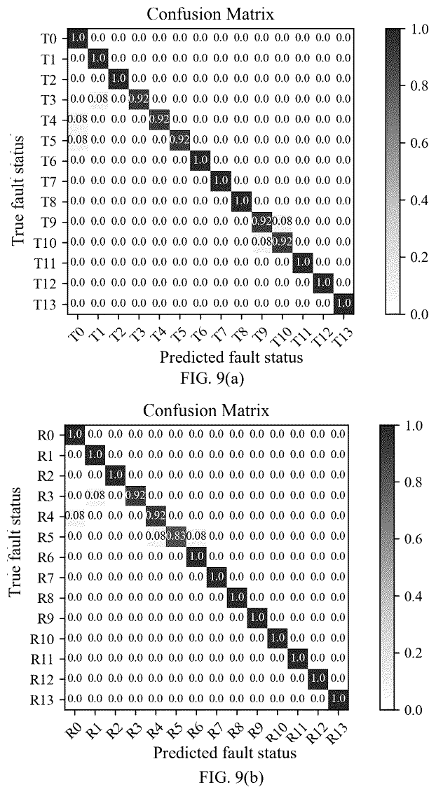

In one embodiment, P fault signals is generated for each fault status, and M×P fault signals are obtained by repeating the experiment until M experiments are completed. By acquiring each fault signal according to step S1 and extracting fault feature according to step S1, a training set is obtained. Afterward, we train the fault identification model by using the training set. The training effects of the fault identification model are shown in FIG. 8(a)˜FIG. 8(b), where FIG. 8(a) is a training effect drawing of a fault identification model for a transmitting branch, which includes a training accuracy curve and a loss curve, FIG. 8(b) is a training effect drawing of a fault identification model for a receiving branch, which includes a training accuracy curve and a loss curve. From FIG. 8(a)˜FIG. 8(b), we can see that the present invention has a fast convergence and exhibits high accuracy and stable loss fluctuations after convergence. Which shows that the present invention has excellent fault diagnosis performance for the RF front-end circuit of a MIMO system.

Lastly, we save the training parameters of the fault identification model and test the fault identification model. In one embodiment, the testing effect illustrations of a fault identification model fused by a complex field based asymmetric convolutional neural network and a complex field based multi-head attention module are shown in FIG. 9(a)˜FIG. 9(b), where FIG. 9(a) is a confusion matrix of a transmitting branch, FIG. 9(b) is a confusion matrix of a receiving branch. In the embodiment, the present invention achieves an average diagnostic accuracy of 99.84% for the transmitting branch. As shown in FIG. 9(a), we can see that the normal status of transmitting branch is T0, while the faults in transmitting branch (fault labels T1, T2, T6, T7, T8, T11, T12 and T13) are correctly diagnosed with a fault diagnosis rate of 100%. However, some faults may be confused, as indicated by fault labels T3, T4, and T5. Fault T3 may be confused with fault T1, and faults T4 and T5 may be confused with normal state T0. The reason for this confusion is that the faulty component is located at the grounding end of the RF front-end circuit, and its fault only causes a slight decrease in transmission power, which will be compensated for through reflected signals and cause fault feature similar to that of other fault, leading to confusion. The present invention achieves an average diagnostic accuracy of 99.06% for the receiving branch. As shown in FIG. 9(b), we can see that the normal status of receiving branch is T0, while the faults in receiving branch (fault labels R1, R2 and R6˜R13) are correctly diagnosed with a fault diagnosis rate of 100%. However, faults labeled as R3, R4, and R5 may be confused with other faults. Specifically, R3 represents a resistance drift fault on the receiving branch. When its negative bias voltage reaches a certain level, this fault will exhibit a similar effect to a short circuit fault, which may cause confusion; Fault R5 may be confused with faults R4 and R6. The reason for this confusion is that the component causing the fault is located at the grounding end of the RF front-end circuit, and its fault only causes a slight decrease in transmission power, which will be compensated for through reflected signals and cause fault feature similar to that of other fault, leading to confusion.

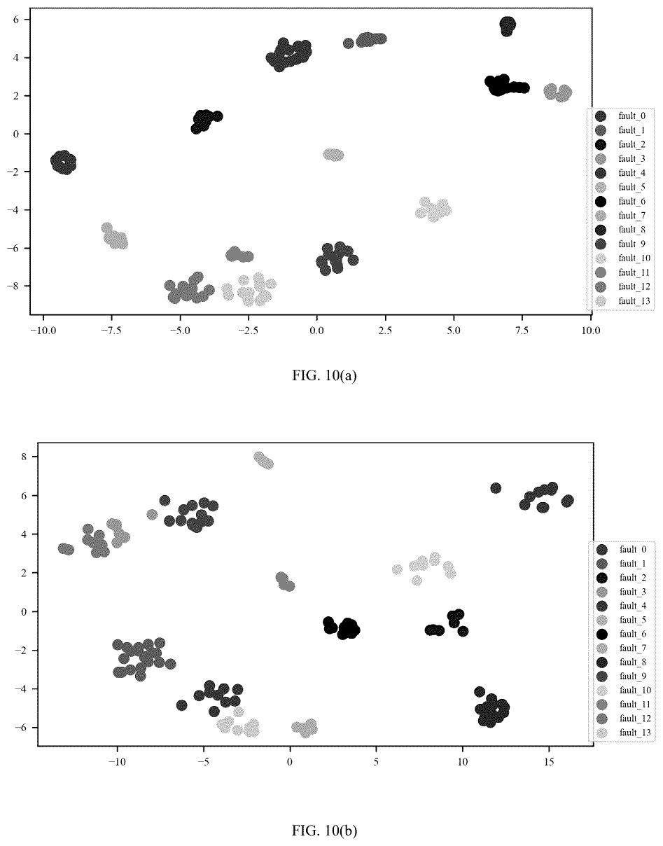

In one embodiment, the present invention, a fault diagnosis method for the RF front-end circuit of a MIMO system performs fault diagnosis on the faults in Table 1, the effect illustrations are shown in FIG. 10(a)˜FIG. 10(b), where FIG. 10(a) is a feature classification illustration of a transmitting branch, when a short time Fourier transform and a SEET are used, where FIG. 10(b) is a feature classification illustration of a receiving branch, when a short time Fourier transform and a SEET are used. From the FIG. 10(a)˜FIG. 10(b), we can see that: when a SEET is used to extract feature components, all type of fault can be distinctly distinguished. Therefore, the present invention can obtain a more effective fault feature and achieve more advantageous fault diagnosis results.

While illustrative embodiments of the invention have been described above, it is, of course, understand that various modifications will be apparent to those of ordinary skill in the art. Such modifications are within the spirit and scope of the invention, which is limited and defined only by the appended claims.

What is claimed is:

1. A method fault diagnosis method for the RF front-end circuit of a MIMO system, comprising:
(1). generating a fault test signal by an upper computer and transmitting the fault test signal to a RF front-end circuit of a MIMO system, then acquiring a fault signal s(t) from an output port of the RF front-end circuit, where t is time;
for a transmitting branch of the RF front-end circuit, the fault test signal is a sweeping signal with power p_{T} and frequency range f_{T1}˜f_{T2}, which is inputted to an input port of the transmitting branch, a fault signal s_{T}(t) acquired from an output port of the transmitting branch is the fault signal s(t), for a receiving branch of the RF front-end circuit, the fault test signal is a sweeping signal with power p_{R} and frequency range f_{R1}˜f_{R2}, which is inputted to an input port of the receiving branch, a fault signal s_{R}(t) acquired from an output port of the receiving branch is the fault signal s(t);
(2). using a Synchronous Enhancement Extracting Transform (hereinafter referred as SEET) to pre-process the acquired fault signal s(t) to extract fault feature components and obtain a real field two-dimensional matrix i and an imaginary field two-dimensional matrix q
2.1). creating a SEET operator \hat{ω}(t, ω):
$$\hat{ω} ( t , ω ) = t - Img [ \frac{{w}_{S}^{{G}^{″}} {w}_{S}^{ω G} - {w}_{S}^{{G}^{′}} {w}_{S}^{ω {G}^{′}}}{{w}_{S}^{G} {w}_{S}^{ω {G}^{′}} - {w}_{S}^{{G}^{′}} {w}_{S}^{ω G}} ]$$
$$s . t . \vert {W}_{S}^{G} {W}_{S}^{ω {G}^{′}} - {W}_{S}^{{G}^{′}} {W}_{S}^{ω G} \vert > ε$$
where [symbol] _{S}^{G}, [symbol] _{S}^{G}′, [symbol] _{S}^{ωG}, [symbol] _{S}^{ωG}′ and [symbol] _{S}^{G}″ are time-frequency distributions obtained by performing short-time Fourier transforms on the acquired fault signal s(t) with window functions g(t), g′(t), tg(t), tg′(t) and g″(t) respectively, Img is a function of extracting the imaginary part of a complex number, s. t. is the abbreviation of “subject to”, ε is an error threshold;
2.2). performing a SEET: SEET(t, ω)= [symbol] _{S}^{G}(t, ω)·δ(ω−\hat{ω}(t, ω)), where δ(·) is Dirichlet function;
2.3). extracting fault feature components sₙ(t)|_{\hat{ω}}_{ₙ}_{(t,ω)}:
$${s}_{n} ( t ) {\vert}_{{\hat{ω}}_{n} ( t , ω )} = \frac{1}{2 π \hat{G} ( 0 )} {\int }_{{\hat{ω}}_{n} ( t , ω )} SEET ( t , ω ) {e}^{j ω t} d ω$$
where n is the serial number of a fault feature component of the fault signal s(t), n=1, 2, . . . , N, N is the total of fault feature components of the fault signal s(t), \hat{ω}ₙ(t, ω) is the n^{th} component of the SEET operator \hat{ω}(t, ω), Ĝ(0) is a value of Fourier transform Ĝ(ω) of the window function g(t) at angular frequency ω=0;
2.4). calculating a real field feature iₙ(t)=Real[sₙ(t)|_{\hat{ω}}_{ₙ}_{(t,ω)}] and an imaginary field feature qₙ(t)=Img[sₙ(t)|_{\hat{ω}}_{ₙ}_{(t,ω)}] respectively according to fault feature components sₙ(t)|_{\hat{ω}}_{ₙ}_{(t,ω)}, n=1, 2, . . . , N, thus the real field two-dimensional matrix i and the imaginary field two-dimensional matrix q are obtained:
$$i = [ \begin{matrix}{i}_{1} ( {t}_{1} ) & {i}_{1} ( {t}_{2} ) & ⋯ & {i}_{1} ( {t}_{L - 1} ) & {i}_{1} ( {t}_{L} ) \\ {i}_{2} ( {t}_{1} ) & {i}_{2} ( {t}_{2} ) & ⋯ & {i}_{2} ( {t}_{L - 1} ) & {i}_{2} ( {t}_{L} ) \\ ⋯ & ⋯ & ⋱ & ⋯ & ⋯ \\ {i}_{N} ( {t}_{1} ) & {i}_{N} ( {t}_{2} ) & ⋯ & {i}_{N} ( {t}_{L - 1} ) & {i}_{N} ( {t}_{L} )\end{matrix} ]$$
$$q = [ \begin{matrix}{q}_{1} ( {t}_{1} ) & {q}_{1} ( {t}_{2} ) & ⋯ & {q}_{1} ( {t}_{L - 1} ) & {q}_{1} ( {t}_{L} ) \\ {q}_{2} ( {t}_{1} ) & {q}_{2} ( {t}_{2} ) & ⋯ & {q}_{2} ( {t}_{L - 1} ) & {q}_{2} ( {t}_{L} ) \\ ⋯ & ⋯ & ⋱ & ⋯ & ⋯ \\ {q}_{N} ( {t}_{1} ) & {q}_{N} ( {t}_{2} ) & ⋯ & {q}_{N} ( {t}_{L - 1} ) & {q}_{N} ( {t}_{L} )\end{matrix} ]$$
where iₙ(tₗ) and qₙ(tₗ) are the values of the n^{th} real field feature iₙ(t) and imaginary field qₙ(t) at time tₗ, l=1,2, . . . , L, respectively;
(3). creating a fault identification model fused by a complex field based asymmetric convolutional neural network and a complex field based multi-head attention module to perform fault identification
3.1). in the complex field based asymmetric convolutional neural network, performing convolutional samplings with a plurality of parallel branches on the real field two-dimensional matrix i to capture the detail features in vertical and horizontal directions, then perform scaling on the convolutional sampling result of each parallel branch, and then fusing the scaled convolutional sampling results of all parallel branches together to obtain a real field two-dimensional matrix i′, performing same convolutional samplings, scalings and fusing on the imaginary field two-dimensional matrix q to obtain an imaginary field two-dimensional matrix q′, lastly, multiplying the real field two-dimensional matrix i′ by trainable parameter matrices Wᵢ^{Q}, Wᵢ^{K} and Wᵢ^{V} to obtain a query matrix Qᵢ, a key matrix Kᵢ and a value matrix Vᵢ respectively, and multiplying the imaginary field two-dimensional matrix q′ by trainable parameter matrices W_{q}^{Q}, W_{q}^{K} and W_{q}^{V} to obtain a query matrix Q_{q}, a key matrix K_{q} and a value matrix V_{q} respectively;
3.2). in the complex field based multi-head attention module, firstly, dividing each of query matrix Qᵢ, key matrix Kᵢ, value matrix Vᵢ, query matrix Q_{q}, key matrix K_{q} and value matrix V_{q} into H matrices: Qᵢ^{(h)}, Kᵢ^{(h)}, Vᵢ^{(h)}, Q_{q}^{(h)}, K_{q}^{(h)} and V_{q}^{(h)}, h=0,1, . . . , H−1, thus obtaining H attention heads' query matrix Q^{(h)}, key matrix K^{(h)}, and value matrix V^{(h)}:
$${Q}^{( h )} = {Q}_{i}^{( h )} + {jQ}_{q}^{( h )}$$
$${K}^{( h )} = {K}_{i}^{( h )} + {jK}_{q}^{( h )}$$
$${V}^{( h )} = {V}_{i}^{( h )} + {jV}_{q}^{( h )} , h = 0 , 1 , … , H - 1$$
then calculating attention weight Attn^{(h)}=Attnᵢ^{(h)}+jAttn_{q}^{(h)} by the h^{th} attention head according to the h^{th} query matrix Q^{(h)}, key matrix K^{(h)}, and value matrix V^{(h)}, h=0,1,2, . . . H−1;
then fusing all attention weights together to obtain multi-head attention Attention:
$$Attention = {Attention}_{i} + {jAttention}_{q}$$
$$where :$$
$${Attention}_{i} = concat ( {Attn}_{i}^{( 0 )} , {Attn}_{i}^{( 1 )} , … , {Attn}_{i}^{( H - 1 )} )$$
$${Attention}_{q} = concat ( {Attn}_{q}^{( 0 )} , {Attn}_{q}^{( 1 )} , … , {Attn}_{q}^{( H - 1 )} )$$
where concat is a function of concatenating the data of the same dimension;
3.3). performing residual connection and outputting a distributed feature X:
$$X = {X}_{i} + {jX}_{q}$$
$$where :$$
$${X}_{i} = {Attention}_{i} + i$$
$${X}_{q} = {Attention}_{q} + q$$
3.4). obtaining corresponding fault status according to the distributed feature X;
(4). setting the network parameters of the fault identification model created by step (3), and training the fault identification model, then using the trained fault identification model to identify fault and obtain a fault status.

2. A fault diagnosis method for the RF front-end circuit of a MIMO system of claim 1, wherein step 3.1) comprises:
3.1.1). using convolutional kernels Conv 3×3, Conv 1×3 and Conv 3×1 by a convolutional sampling layer to perform convolutional samplings on the real field two-dimensional matrix i respectively, so as to capture the detail features in vertical and horizontal directions, wherein the operation results of the convolutional sampling layer are W^{3×3}, W^{1×3} and W^{3×1}, the corresponding convolution kernels are denoted as k^{3×3}, k^{1×3} and k^{3×1} and the convolution operation is denoted as ⊗, then the operation results of the convolutional sampling layer are as follows:
$${W}^{3 \times 3} = {k}^{3 \times 3} ⊗ i , {W}^{1 \times 3} = {k}^{1 \times 3} ⊗ i , {W}^{3 \times 1} = {k}^{3 \times 1} ⊗ i$$
3.1.2). performing a scaling on the convolutional sampling result of each parallel branch by a batch normalization layer, wherein the expectations for the parallel branches are denoted as μ^{3×3}, μ^{1×3} and μ^{3×1} respectively, the scale factors for the parallel branches are denoted as
$$\frac{{λ}^{3 \times 3}}{{σ}^{3 \times 3}} , \frac{{λ}^{1 \times 3}}{{σ}^{1 \times 3}} and \frac{{λ}^{3 \times 1}}{{σ}^{3 \times 1}}$$
respectively, the errors for the parallel branches are denoted as ξ^{3×3}, ξ^{1×3} and ξ^{3×1} respectively, the operation results of the batch normalization layer are denoted as W′^{3×3}, W′^{1×3} and W′^{3×1} respectively, then the operation results of the batch normalization layer are as follows:
$${W}^{′3 \times 3} = \frac{{λ}^{3 \times 3}}{{σ}^{3 \times 3}} \cdot ( {W}^{3 \times 1} - {μ}^{3 \times 3} ) + {ξ}^{3 \times 3}$$
$${W}^{′ 1 \times 3} = \frac{{λ}^{1 \times 3}}{{σ}^{1 \times 3}} \cdot ( {W}^{1 \times 3} - {μ}^{1 \times 3} ) + {ξ}^{1 \times 3}$$
$${W}^{′ 3 \times 1} = \frac{{λ}^{3 \times 1}}{{σ}^{3 \times 1}} \cdot ( {W}^{3 \times 1} - {μ}^{3 \times 1} ) + {ξ}^{3 \times 1}$$
3.1.3). firstly, adding detailed features to the corresponding horizontal and vertical positions of the 3×3 square convolution kernel based on the additive properties of the convolution kernel by a branch fusion layer, achieving branch fusion and obtaining a real field two-dimensional matrix i′:
$${i}^{′} = {W}^{′ 3 \times 3} ⊕ {W}^{′ 1 \times 3} ⊕ {W}^{′ 3 \times 1}$$
where ⊕ is a branch fusion operation.
performing the same convolutional samplings, scalings and fusing on the imaginary field two-dimensional matrix q to obtain an imaginary field two-dimensional matrix q′ by the batch normalization layer according to steps 3.1.1)˜S3.1.3);
then, multiplying the real field two-dimensional matrix i′ by trainable parameter matrices Wᵢ^{Q}, Wᵢ^{K} and Wᵢ^{V} to obtain a query matrix Qᵢ, a key matrix Kᵢ and a value matrix Vᵢ by the branch fusion layer respectively, and multiplying the imaginary field two-dimensional matrix q′ by trainable parameter matrices W_{q}^{Q}, W_{q}^{K} and W_{q}^{V} to obtain a query matrix Q_{q}, a key matrix K_{q} and a value matrix V_{q} by the branch fusion layer respectively.

3. A fault diagnosis method for the RF front-end circuit of a MIMO system of claim 1, in step 3.2), calculating attention weight Attn^{(h)}=Attnᵢ^{(h)}+jAttn_{q}^{(h)} by the h^{th} attention head according to the h^{th} query matrix Q^{(h)}, key matrix K^{(h)}, and value matrix V^{(h)}, h=0,1,2, . . . H−1 is:
calculating attention scores: performing a matrix operation:
$$\begin{matrix}AttnMult ( {Q}^{( h )} , {K}^{( h )} ) & = \frac{{Q}^{( h )} {K}^{{( h )}^{T}}}{\sqrt{{d}_{ρ}}} \\ & = ( {Q}_{i}^{( h )} + {jQ}_{q}^{( h )} ) {( {K}_{i}^{( h )} + {jK}_{q}^{( h )} )}^{T} / \sqrt{{d}_{ρ}} \\ & = ( {Q}_{i}^{( h )} {K}_{i}^{{( h )}^{T}} - {Q}_{q}^{( h )} {K}_{q}^{{( h )}^{T}} ) / \sqrt{{d}_{ρ}} + j ( {Q}_{q}^{( h )} {K}_{i}^{{( h )}^{T}} + {Q}_{i}^{( h )} {K}_{q}^{{( h )}^{T}} ) / \sqrt{{d}_{q}}\end{matrix}$$
letting AttnMultᵢ^{(h)}=(Qᵢ^{(h)}Kᵢ^{(h)}^{^{T}}−Q_{q}^{(h)}K_{q}^{(h)}^{^{T}})/\sqrt{d_{ρ}}, AttnMult_{q}^{(h)}=(Q_{q}^{(h)}Kᵢ^{(h)}^{^{T}}−Qᵢ^{(h)}K_{q}^{(h)}^{^{T}})/\sqrt{d_{ρ}}, then the attention scores of the h^{th} attention head are:
AttnScoreᵢ^{(h)}=softmax(AttnMultᵢ^{(h)})
AttnScore_{q}^{(h)}=softmax(AttnMult_{q}^{(h)})
calculating an attention weight: multiplying the attention scores by value matrix, then each attention weight can be obtained, the processes of calculating an attention weight are as follows:
$${Attn}^{( h )} = ( {AttnScore}_{i}^{( h )} + {jAttnScore}_{q}^{( h )} ) {( {V}_{i}^{( h )} + {jV}_{q}^{( h )} )}^{T} = ( {AttnScore}_{i}^{( h )} {V}_{i}^{{( h )}^{T}} - {AttnScore}_{q}^{( h )} {V}_{q}^{{( h )}^{T}} ) + j ( {AttnScore}_{i}^{( h )} {V}_{q}^{{( h )}^{T}} + {AttnScore}_{q}^{( h )} {V}_{i}^{{( h )}^{T}} )$$
$${Attn}_{i}^{( h )} = {AttnScore}_{i}^{( h )} {V}_{i}^{{( h )}^{T}} - {AttnScore}_{q}^{( h )} {V}_{q}^{{( h )}^{T}}$$
$${Attn}_{q}^{( h )} = {AttnScore}_{i}^{( h )} {V}_{q}^{{( h )}^{T}} + {AttnScore}_{q}^{( h )} {V}_{i}^{{( h )}^{T}}$$
the obtained attention weight is Attn^{(h)}=Attnᵢ^{(h)}+jAttn_{q}^{(h)}.
